(19) United States
(12) Patent Application Publication
(10) Pub. No.: US 2026/0223486 A1
(43) Pub. Date: Jul. 30, 2026

(54) METHOD FOR MANUFACTURING CHIP-ON-WAFER FOR MICRO LED DISPLAY

(71) Applicant: WAVELORD CO., LTD, Hwaseong-si (KR)

(72) Inventors: Juneo SONG, Suwon-si (KR); Ji Hyung MOON, Gunpo-si (KR)

(73) Assignee: WAVELORD CO., LTD, Hwaseong-si (KR)

(21) Appl. No.: 19/145,898

(22) PCT Filed: Aug. 13, 2024
(86) PCT No.: PCT/KR2024/012080

§ 371 Date: Jul. 4, 2025

(30) Foreign Application Priority Data
Sep. 5, 2023 (KR) 10-2023-0117751

(51) Int. Cl. H10H 20/01

(52) U.S. Cl. CPC H10H 20/018; H10H 20/017; H10H 20/032; H10H 20/034; H10H 20/0364

(57) ABSTRACT

The present invention relates to a method of manufacturing a chip-on-wafer for a micro-LED display, whereby a lateral chip, a flip chip, and a vertical chip for a high-quality, high-brightness micro LED display having a thickness of at most 3 μm can be manufactured by molding an undoped semiconductor region to a desired thickness without damaging the chips when manufacturing the chips for a micro LED display using a chip-on-wafer method.

### TECHNICAL FIELD

The present invention relates to a method of manufacturing a chip-on-wafer for a micro-light-emitting diode (LED) display, and more particularly, to a method of manufacturing a chip-on-wafer for a micro-LED display in which, in manufacturing a lateral chip, a flip chip, and a vertical chip for a micro-LED display by using a chip-on-wafer method, an undoped semiconductor region (for example, uGaN, uInGaN, uAlGaN, uAlGaInN, uGaP, uInGaP, uAlGaP, or uAlGaInP) is formed to have a desired thickness without damage to a chip, thereby manufacturing a chip for a high-quality and high-brightness micro-LED display with a thickness of 3 μm or less.

### BACKGROUND ART

In general, micro-light-emitting diode (LED) displays including mini LED displays may be classified into micro-LED displays using a passive matrix (PM) driving method and micro-LED displays using an active matrix (AM) driving method.

Here, PM-driven micro-LED displays typically have a sapphire support substrate, which finally remains, and use sorted thick blue, green, and red (BGR) chips (wherein both an anode and a cathode of an LED are completed), which are transferred using a chip die-level process in which either horizontal chips or flip chips may generally be used.

In addition, AM-driven micro-LED displays typically do not have a sapphire support substrate, which finally remains, and use unsorted thin BGR chips (wherein both an anode and a cathode of an LED are completed), which are transferred using a wafer-level process in which horizontal chips, flip chips, or vertical chips may all be generally utilized.

Recently, smaller compact chips have become necessary for manufacturing micro-level LED displays. In response to these market demands, micro-LED display chips currently being manufactured have a thickness of 5 μm to 7 μm, but it is reported that a thickness of 5 μm or less is difficult to achieve due to issues such as chip breakage.

Meanwhile, a chip-on-wafer method is a method in which the entire process from a process of epitaxially growing a semiconductor layer on an initial growth substrate to a final fab process is performed on the initial growth wafer.

According to such conventional chip-on-wafer methods, since a stack structure of a chip is completed using only an initial growth substrate, the thickness of an undoped semiconductor region (uGaN) or an n-type semiconductor region (nGaN) cannot be controlled, which makes it impossible to manufacture micro-LEDs with a thickness of 5 μm or less. In addition, there is also a disadvantage in that light extraction efficiency is reduced by such a thick undoped semiconductor region (for example, uGaN, uInGaN, uAlGaN, uAlGaInN, uGaP, uInGaP, uAlGaP, or uAlGaInP).

Meanwhile, in conventional chip-on-wafer methods, a completed chip is attached to thin film transistor (TFT) glass, an interposer, or the like, and then an initial growth substrate on an opposite surface may be removed to expose an undoped semiconductor region (for example, uGaN, uInGaN, uAlGaN, uAlGaInN, uGaP, uInGaP, uAlGaP, or uAlGaInP). However, even when the undoped semiconductor region (for example, uGaN, uInGaN, uAlGaN, uAlGaInN, uGaP, uInGaP, uAlGaP, or uAlGaInP) is to be etched, there is a problem in that a completed chip is damaged by a high temperature generated during etching and an injected gas.

Furthermore, when an initial growth substrate is removed through a laser lift-off (LLO) process, a large number of gallium (Ga) droplets (solids or powders) that interfere with the scattering of generated light are generated on a surface of a semiconductor layer from which the initial growth substrate has been removed. Currently, the gallium (Ga) droplets are removed through hydrochloric acid vapor or taping. However, when hydrochloric acid vapor is used, there are problems in that process costs may be excessive and a chip may be damaged during a gallium (Ga) droplet removal process. In addition, when taping is used, there is a problem in that complete removal of the gallium (Ga) droplets is impossible. However, when a growth substrate for Si (a nitride that emits blue, green, or red light) and GaAs (a phosphide that emits red light) micro-LEDs is removed through a chemical lift-off (CLO) process, there is no gallium (Ga) droplet issue.

In addition, according to conventional chip-on-wafer methods, since a chip stack structure is completed using only an initial growth substrate, ohmic contact electrodes have to be formed in a back-end process. In this case, since heat treatment at a temperature of 300° C. or more should be essentially performed to form ohmic contact electrodes, there is also a problem in that a chip in which a plurality of layers have already been stacked and formed is damaged by high temperatures.

### DESCRIPTION OF INVENTION

### Technical Problem

The present invention is directed to solving the above conventional problems and providing a method of manufacturing a chip-on-wafer for a micro-light-emitting diode (LED) display in which, in manufacturing a lateral chip, a flip chip, and a vertical chip for a micro-LED display by using a chip-on-wafer method, an undoped semiconductor region (for example, uGaN, uInGaN, uAlGaN, uAlGaInN, uGaP, uInGaP, uAlGaP, or uAlGaInP) is formed to have a desired thickness without damage to a chip, thereby manufacturing a chip for a high-quality and high-brightness micro-LED display with a thickness of 3 μm or less.

### Technical Solution

The object is achieved by a method of manufacturing a chip-on-wafer for a micro-light-emitting diode (LED) display, which includes a growth operation of epitaxially growing a semiconductor layer on a growth substrate, an electrode formation operation of forming an ohmic contact electrode on the semiconductor layer, a bonding operation of bonding the ohmic contact electrode to a support substrate, and an exposure operation of removing the growth substrate to expose one surface of the semiconductor layer.

In addition, according to the present invention, the method may further include a formation operation of etching the exposed one surface of the semiconductor layer to form the semiconductor layer to have a preset thickness.

In addition, the growth operation may include sequentially and epitaxially growing a third semiconductor region, a second semiconductor region, an active region, and a first semiconductor region, the formation operation may include etching the exposed third semiconductor region to form the semiconductor layer to have the preset thickness, and the third semiconductor region may be an undoped semiconductor region.

In addition, according to the present invention, the method may further include a pattern formation operation of forming a surface texture pattern on the exposed one surface of the semiconductor layer.

In addition, according to the present invention, the method may further include a reflective layer formation operation of forming a reflective layer on the one surface of the semiconductor layer on which the surface texture pattern is formed.

In addition, according to the present invention, the method may further include a reflective layer formation operation of forming a reflective layer on the exposed one surface of the semiconductor layer.

In addition, the reflective layer may be in ohmic contact with the one surface of the semiconductor layer.

In addition, the bonding operation may include forming a separation layer on the support substrate and then bonding the one surface of the semiconductor layer to the separation layer.

The object is achieved by a method of manufacturing a chip-on-wafer for a micro-LED display, which includes a growth operation of epitaxially growing a semiconductor layer on a growth substrate, an electrode formation operation of forming an ohmic contact electrode on the semiconductor layer, a reflective layer formation operation of forming a reflective layer on the ohmic contact electrode, a bonding operation of bonding the reflective layer to a support substrate, and an exposure operation of removing the growth substrate to expose one surface of the semiconductor layer.

In addition, according to the present invention, the method may further include a formation operation of etching the exposed one surface of the semiconductor layer to form the semiconductor layer to have a preset thickness.

In addition, the growth operation may include sequentially and epitaxially growing a third semiconductor region, a second semiconductor region, an active region, and a first semiconductor region, the formation operation may include etching the exposed third semiconductor region to form the semiconductor layer to have the preset thickness, and the third semiconductor region may be an undoped semiconductor region.

In addition, according to the present invention, the method may further include a pattern formation operation of forming a surface texture pattern on the exposed one surface of the semiconductor layer.

In addition, according to the present invention, the method may further include a transmissive layer formation operation of forming a transmissive layer on the one surface of the semiconductor layer on which the surface texture pattern is formed.

In addition, according to the present invention, the method may further include a transmissive layer formation operation of forming a transmissive layer on the exposed one surface of the semiconductor layer.

In addition, the transmissive layer may be in ohmic contact with the one surface of the semiconductor layer.

In addition, the bonding operation may include forming a separation layer on the support substrate and then bonding the one surface of the semiconductor layer to the separation layer.

### Advantageous Effects

According to the present invention, in manufacturing a lateral chip, a flip chip, and a vertical chip for a micro-light-emitting diode (LED) display by using a chip-on-wafer method, an undoped semiconductor region (for example, uGaN, uInGaN, uAlGaN, uAlGaInN, uGaP, uInGaP, uAlGaP, or uAlGaInP) can be formed to have a desired thickness without damage to a chip, thereby manufacturing a chip for a high-quality and high-brightness micro-LED display with a thickness of 3 μm or less, and a problem in which gallium (Ga) droplets remaining on a surface of a semiconductor layer can be fundamentally prevented, thereby significantly improving light extraction efficiency.

In addition, according to the present invention, after a semiconductor layer is grown, an ohmic contact electrode is formed through high-temperature heat treatment in a state in a which other layers are not stacked, and then the remaining necessary layers such as a reflective layer are stacked on one surface of the semiconductor layer, thereby fundamentally preventing a problem in which a stacked and formed chip is damaged by high-temperature heat treatment when the ohmic contact electrode is formed.

Meanwhile, the effects of the present invention are not limited to the above-described effects, and various effects may be included within the range apparent to those skilled in the art from content to be described below.

### DESCRIPTION OF DRAWINGS

FIG. 1 illustrates an overall process of manufacturing a chip-on-wafer according to a method of manufacturing a chip-on-wafer for a micro-light-emitting diode (LED) display according to the present invention.

FIG. 2 is a flowchart of a method of manufacturing a chip-on-wafer for a micro-LED display according to a first second embodiment of the present invention.

FIG. 3 illustrates a process of manufacturing a chip-on-wafer according to the method of manufacturing a chip-on-wafer for a micro-LED display according to the first embodiment of the present invention.

FIG. 4 is a flowchart of a method of manufacturing a chip-on-wafer for a micro-LED display according to a second embodiment of the present invention.

FIG. 5 illustrates a process of manufacturing a chip-on-wafer according to the method of manufacturing a chip-on-wafer for a micro-LED display according to the second embodiment of the present invention.

FIG. 6 is a flowchart of a method of manufacturing a chip-on-wafer for a micro-LED display according to a third embodiment of the present invention.

FIG. 7 illustrates a process of manufacturing a chip-on-wafer according to the method of manufacturing a chip-on-wafer for a micro-LED display according to the third embodiment of the present invention.

FIG. 8 is a flowchart of a method of manufacturing a chip-on-wafer for a micro-LED display according to the fourth embodiment of the present invention.

FIG. 9 illustrates a process of manufacturing a chip-on-wafer according to the method of manufacturing a chip-on-wafer for a micro-LED display according to the fourth embodiment of the present invention.

FIG. 10 illustrates a vertical chip manufactured using the chip-on-wafer manufactured according to the method of manufacturing a chip-on-wafer for a micro-LED display according to the first embodiment of the present invention.

FIG. 11 illustrates a vertical chip manufactured using the chip-on-wafer manufactured according to the method of manufacturing a chip-on-wafer for a micro-LED display according to the second embodiment of the present invention.

FIG. 12 illustrates a vertical chip manufactured using the chip-on-wafer manufactured according to the method of manufacturing a chip-on-wafer for a micro-LED display according to the third embodiment of the present invention.

FIG. 13 illustrates a vertical chip manufactured using the chip-on-wafer manufactured according to the method of manufacturing a chip-on-wafer for a micro-LED display according to the fourth embodiment of the present invention.

### MODES OF THE INVENTION

Hereinafter, some embodiments of the present invention will be described in detail with the accompanying exemplary drawings. When reference numerals refer to components of each drawing, even when the same components are illustrated in different drawings, the same components will be referred to by the same reference numerals where possible.

Further, in describing the present invention, detailed description of related known configurations and functions will be omitted when it is determined that it may obscure understanding of the embodiments of the present invention.

In addition, in describing components of the embodiment of the present invention, terms such as “first,” “second,” “A,” “B,” “(a),” and “(b) may be used. The terms are used to distinguish one component from another component. However, the nature, order, sequence, or numbers of components are not limited by the terms.

Hereinafter, a method S100 of manufacturing a chip-on-wafer for a micro-light-emitting diode (LED) display according to a first embodiment of the present invention will be described in detail with reference to the accompanying drawings.

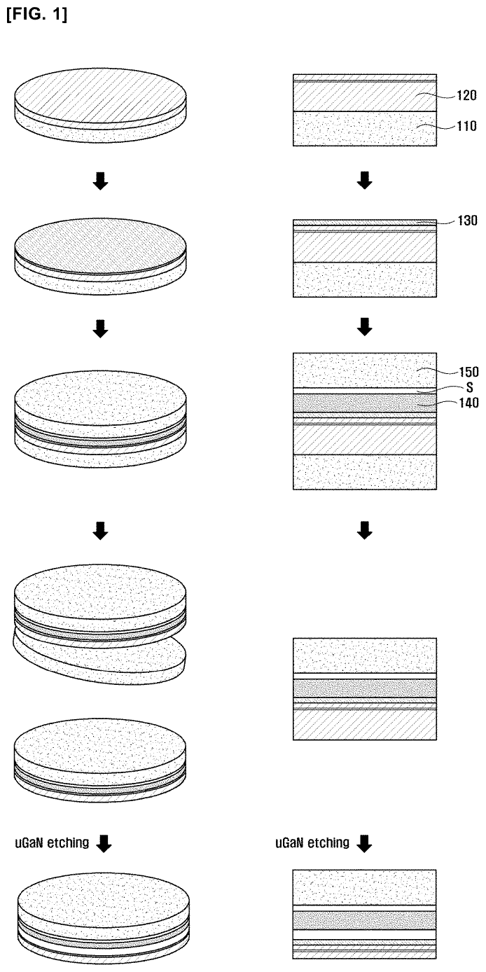

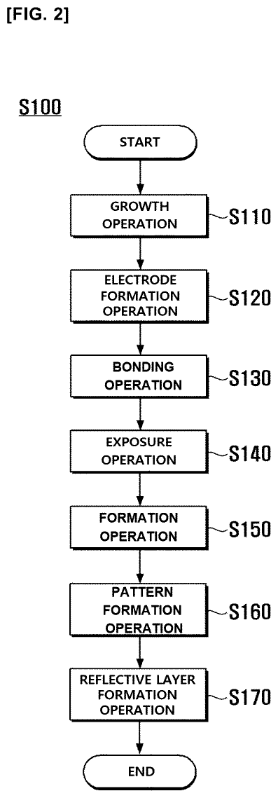

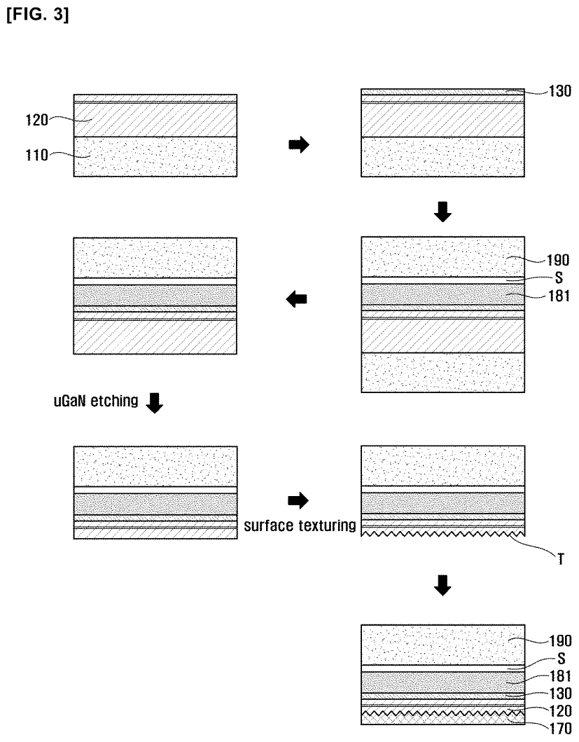

FIG. 1 illustrates an overall process of manufacturing a chip-on-wafer according to a method of manufacturing a chip-on-wafer for a micro-LED display according to the present invention, FIG. 2 is a flowchart of the method of manufacturing a chip-on-wafer for a micro-LED display according to the first embodiment of the present invention, and FIG. 3 shows views illustrating a process of manufacturing a chip-on-wafer according to the method of manufacturing a chip-on-wafer for a micro-LED display according to the first embodiment of the present invention.

As shown in FIGS. 1 to 3, a chip-on-wafer is manufactured through a one-time bonding method, and the method S100 of manufacturing a chip-on-wafer for a micro-LED display according to the first embodiment of the present invention includes a growth operation S110, an electrode formation operation S120, a bonding operation S130, an exposure operation S140, a formation operation S150, a pattern formation operation S160, and a reflective layer formation operation S170.

In a case in which a semiconductor layer 120 emits blue or green light, when a laser lift-off (LLO) process is used to remove an initial growth substrate 110, a substrate may be provided as an optically transparent and high-temperature heat-resistant sapphire (α-phase Al₂O₃) substrate that may (theoretically) transmit 100% of a laser beam (single wavelength light) without absorption, and when a chemical lift-off (CLO) process is used to remove the initial growth substrate 110, a substrate may be provided as a Si substrate having a (111), (110), or (100) crystal plane that may be removed through wet etching.

Meanwhile, when the initial growth substrate 110 is provided as a sapphire substrate, it is also preferable that the initial growth substrate 110 have a protrusion shape that is patterned regularly or irregularly in various dimensions (sizes and shapes) on a microscale or nanoscale in order to minimize crystal defects in a Group III nitride semiconductor thin film grown thereon (patterned sapphire substrate (PSS)).

In addition, when the semiconductor layer 120 emits red light, the initial growth substrate 110 may be prepared as a GaAs substrate that may be removed through wet etching using a CLO process. Furthermore, when the semiconductor layer 120 emits red light through a high-quality InGaN active region having a high In composition of 30% or more, the initial growth substrate 110 may be provided as a sapphire or Si substrate as in a case in which the semiconductor layer 120 emits blue or green light.

The semiconductor layer 120 generates light and includes a third semiconductor region, a second semiconductor region, an active region, and a first semiconductor region.

In the present invention, the semiconductor layer 120 may emit blue, green, or red light, and when the semiconductor layer 120 emits blue or green light, a binary, ternary, or quaternary compound such as InN, InGaN, GaN, AlGaN, AlN, or AlGaInN, which is a Group III (Al, Ga, or In) nitride semiconductor among Group III-V compound semiconductors, may be disposed at an appropriate position and order on the initial growth substrate 110 and epitaxially grown.

In particular, in order to emit blue light or green light, a high-quality Group III nitride semiconductor such as InGaN having a high indium (In) composition should be preferentially formed on a Group III nitride semiconductor (active region) consisting of GaN, AlGaN, AlN, or AlGaInN, but the present invention is not limited thereto.

In addition, in the present invention, when the semiconductor layer 120 emits red light, a binary, ternary, or quaternary compound such as InP, InGaP, GaP, AlInP, AlGaP, AlP, or AlGaInP, which are Group III (Al, Ga, or In) phosphide semiconductors among Group III-V compound semiconductors, may be disposed at an appropriate position and order on the initial growth substrate 110 and epitaxially grown.

In particular, in order to emit red light, a high-quality Group III phosphide semiconductor such as InGaP having a high In composition should be preferentially formed on a Group III phosphide semiconductor consisting of GaP, AlInP, AlGaP, AlP, or AlGaInP, but the present invention is not limited thereto. Hereinafter, for convenience of description, a Group III nitride semiconductor will be mainly described.

Furthermore, in order to further improve the development of equipment and process technologies and the value of display panel products, when red light is emitted, rather than a Group III phosphide semiconductor, a high-quality Group III nitride semiconductor such as InGaN having a high In composition of 30% or more may be preferentially formed on a Group III nitride semiconductor (active region) consisting of GaN, AlGaN, AlN, or AlGaInN. Specifically, in a case in which an active region consists of InₓGa₁₋ₓN, when x, that is, a composition of indium, is in a range of 16% to 20%, blue light in a wavelength band of 450 nm to 470 nm is emitted, when a composition of indium is in a range of 22% to 28%, green light in a wavelength band of 525 nm to 540 nm is emitted, and when a composition of indium is in a range of 30% to 35% (preferably 33%), red light in a wavelength band of 625 nm to 635 nm is emitted.

More specifically, in the growth operation S110, a third semiconductor region (for example, uInGaN, uAlGaN, or uAlGaInN) which is an undoped semiconductor region, a second semiconductor region (for example, nGaN, nInGaN, nAlGaN, or nAlGaInN) which is an n-type semiconductor region, an active region with a multi-quantum well (MQW) structure, and a first semiconductor region (for example, pGaN, pInGaN, pAlGaN, or nAlGaInN) which is a p-type semiconductor region may be sequentially and epitaxially grown on the initial growth substrate 110, and finally, the semiconductor layer 120 may typically have an overall thickness of about 5.0 μm to about 7.0 μm by ultimately including a plurality of layers of Group III nitrides, but the present invention is not limited thereto.

The third semiconductor region is an undoped semiconductor region, and specifically, before the second semiconductor region, the active region, and the first semiconductor region are epitaxially grown on the initial growth substrate 110, the third semiconductor region is a region that serves as a buffer to relieve the stress of the epitaxially grown second semiconductor region, active region, and first semiconductor region and improve film quality.

The third semiconductor region may include a nucleation layer (NL) and may be formed to typically have a thickness of 2.5 μm to 3 μm. In addition, when the initial growth substrate 110 is removed using an LLO technique, a sacrificial layer (SL) may be provided between the NL and the third semiconductor region and the NL layer may also serve as the SL.

The second semiconductor region has n-type conductivity and is formed on the third semiconductor region. This second semiconductor region may have a thickness of 2.0 μm to 2.5 μm, and a lower surface thereof has nitrogen polarity (N-polarity).

The active region has a multi-quantum well structure, generates light using the recombination of electrons and holes, and is formed on the second semiconductor region. The active region may be provided as a plurality of layers to have a thickness of about 50 nm.

The first semiconductor region has p-type conductivity and is formed on the active region. The first semiconductor region may be provided as a plurality of layers to have a thickness of 0.5 μm or less, and an upper surface thereof may have gallium polarity (Ga-polarity).

That is, the active region is interposed between the second semiconductor region and the first semiconductor region, and when electrons in the second semiconductor region which is an n-type semiconductor region and holes in the first semiconductor region which is a p-type semiconductor region recombine in the active region, light is generated.

The electrode formation operation S120 is an operation of forming an ohmic contact electrode 130 on the semiconductor layer 120.

According to a conventional chip-on-wafer method, since a stack structure of a chip (including a horizontal chip, a flip chip, and a vertical chip) is completed using only the initial growth substrate 110, a p-type ohmic contact electrode 130 should be formed in a back-end process. In this case, since heat treatment should be essentially performed at a temperature of 450° C. or more to form the p-type ohmic contact electrode 130, there is a problem in that a chip in which a plurality of layers have already been stacked is damaged by the high temperature.

Accordingly, in the present invention, after the semiconductor layer 120 is grown, the p-type ohmic contact electrode 130 is formed through high-temperature heat treatment in a state in a which other layers are not stacked (that is, in a state in which a structure of a chip is not completed), and then the remaining necessary layers such as a reflective layer 170 are stacked on one surface of the semiconductor layer 120, thereby fundamentally preventing a problem in which a stacked and formed chip is damaged by the high-temperature heat treatment for forming the p-type ohmic contact electrode 130.

More specifically, in the present invention, the ohmic contact electrode 130 is formed in contact with the first semiconductor region which is a p-type semiconductor and is formed as the p-type ohmic contact electrode 130. Since the p-type ohmic contact electrode 130 is used in a vertical chip structure in the present embodiment, the p-type ohmic contact electrode 130 is made of a transparent and conductive material such that light from below is transmitted upward. In this case, a material of the ohmic contact electrode 130 may include NiO, PtO, PdO, AgO₂, Au, Rh₂O₃, RuO₂, In₂O₃, SnO₂, ZnO, indium zinc oxide (IZO), indium tin oxide (ITO), or indium gallium zinc (IGZO).

Meanwhile, in the present invention, the p-type ohmic contact electrode 130 may have a single-layer structure and may have a multilayer structure in which the thin p-type ohmic contact electrode 130 is first formed on a gallium polarity (Ga-polarity) surface, and then a p-type electrode is formed thereon using a material that is the same as or different from that of the p-type ohmic contact electrode 130 and is electrically connected.

The bonding operation S130 is an operation of bonding the ohmic contact electrode 130 to a final support substrate 190 through a bonding layer 181.

Here, the final support substrate 190 is a substrate that supports a structure of a chip that has undergone each operation of the method S100 of manufacturing a chip-on-wafer for a micro-LED display according to the first embodiment of the present invention. The support substrate 190 may be provided using a sapphire (α-phase Al₂O₃) substrate or glass with an adjusted coefficient of thermal expansion (CTE).

In addition, in the present embodiment, the bonding layer 181 may include a flowable oxide (FOₓ) such as SiO₂, SiNₓ, SiCN, AlN, Al₂O₃, spin-on-glass (SOG, liquid SiO₂), or hydrogen silsesquioxane (HSQ) to transmit generated light.

Meanwhile, in the bonding operation S130, a separation layer S may be formed on the support substrate 190, and then the ohmic contact electrode 130 may be bonded to the separation layer S. The separation layer S may be a layer that is sacrificed and separated when the final support substrate 190 is removed, and a material according to an LLO process may be used. Meanwhile, the separation layer S may be located on or below the bonding layer 181 according to the purpose, and when the bonding layer 181 performs a function of the separation layer S, the separation layer S may be omitted.

The exposure operation S140 is an operation of removing the growth substrate 110 to expose one surface of the semiconductor layer 120.

Specifically, in the exposure operation S140, the third semiconductor region which is an undoped semiconductor region may be exposed to the outside by removing the initial growth substrate 110 using an LLO process or a CLO process.

The formation operation S150 is an operation of selectively etching the exposed one surface of the semiconductor layer 120 to form the semiconductor layer 120 to have a preset thickness.

According to a conventional chip-on-wafer method, since a stack structure of a chip (including a horizontal chip, a flip chip, and a vertical chip) is completed using only the initial growth substrate 110, a thickness of an undoped semiconductor region (for example, uGaN, uInGaN, uAlGaN, or uAlGaInN) or an n-type semiconductor region (for example, nGaN, nInGaN, nAlGaN, or nAlGaInN) cannot be controlled, which makes it impossible to manufacture a high-quality and high-brightness micro-LED having a thickness of 5 μm or less. In addition, there is also a disadvantage in that light extraction efficiency is reduced by such a thick undoped semiconductor region (for example, uGaN, uInGaN, uAlGaN, or uAlGaInN).

Meanwhile, in a conventional chip-on-wafer method, a completed chip may be attached to thin film transistor (TFT) glass, an interposer, or the like, and then the initial growth substrate 110 on an opposite surface may be removed to expose an undoped semiconductor region (for example, uGaN, uInGaN, uAlGaN, or uAlGaInN). However, even when the undoped semiconductor region (for example, uGaN, uInGaN, uAlGaN, or uAlGaInN) is to be etched, there is a problem in that a completed chip is damaged by a high temperature generated during etching and an injected gas.

Furthermore, when the initial growth substrate 110 is removed through an LLO process, a large number of gallium (Ga) droplets (solids or powders) that interfere with the scattering of generated light are generated on a surface of the semiconductor layer 120 from which the initial growth substrate 110 has been removed. Currently, the gallium (Ga) droplets are removed through hydrochloric acid vapor or taping. However, when hydrochloric acid vapor is used, there is problems in that process costs may be excessive and a chip may be damaged during the gallium (Ga) droplet removal process. In addition, when taping is used, there is also a problem in that complete removal of the gallium (Ga) droplets is impossible. However, when a growth substrate for Si (a nitride for blue, green, or red light) and GaAs (a phosphide for red light) micro-LEDs is removed through a CLO process, there is no gallium (Ga) droplet issue.

Accordingly, in the present invention, after the ohmic contact electrode 130 on the semiconductor layer 120 is bonded to an intermediate temporary substrate 150, the initial growth substrate 110 may be removed in a state in which other layers are not stacked (that is, in a state in which a structure of a chip is not complete), and then an exposed undoped semiconductor region (for example, uGaN, uInGaN, uAlGaN, or uAlGaInN) may be etched to form the semiconductor layer 120 to have a preset thickness. Thus, the undoped semiconductor region (for example, uGaN, uInGaN, uAlGaN, or uAlGaInN) can be formed to have a desired thickness without damage to a chip, thereby manufacturing a chip for a high-quality and high-brightness micro-LED display with a thickness of 3 μm or less, and a problem in which gallium (Ga) droplets remaining on the surface of the semiconductor layer 120 can be fundamentally prevented, thereby significantly improving light extraction efficiency.

Specifically, in the formation operation S150, the semiconductor layer 120 is formed to have a preset thickness by etching the third semiconductor region, which is an undoped semiconductor region exposed by removing the growth substrate 110. In the formation operation S150, by using a dry process using known gas (Cl₂, BCl₃, or Ar) plasma, the third semiconductor region with a thickness of 2.5 μm to 3 μm may be etched to have a desired thickness, or the entire third semiconductor region may be etched and removed. In this case, in the present invention, even when a high temperature is generated during the etching of the third semiconductor region, since only the semiconductor layer 120 and the ohmic contact electrode 130 are formed, and a structure of a chip is not yet completed, a thickness of the chip can be adjusted as desired without damage to the chip, and there is an advantage in that gallium (Ga) droplets can be completely removed through etching.

The pattern formation operation S160 is an operation of forming a surface texture pattern T on one surface of the semiconductor layer 120 formed to have a preset thickness.

More specifically, in the pattern formation operation S160, in order to increase light extraction efficiency through light scattering, the surface texture pattern T that is regular or irregular is formed on one surface of the semiconductor layer 120 having a nitrogen polarity (N-polarity) surface using a wet process using a basic solution (including OH, NaOH, or KOH) or a dry process using known gas (Cl₂, BCl₃, or Ar) plasma.

The reflective layer formation operation S170 is an operation of forming the reflective layer 170 on one surface of the semiconductor layer 120 on which the surface texture pattern T is formed.

The reflective layer 170 may be made of Ag, Al, Au, Pd, Pt, Ni, Mo, Cu, Cr, Ti, TiW, ITO, IZO, ZnO, TiN, a distributed Bragg reflector (DBR), an omni-directional reflector (ODR), or a combination thereof, and in the present embodiment, the reflective layer 170 may be formed on one surface of the semiconductor layer 120, that is, the nitrogen polarity (N-polarity) surface.

Meanwhile, the reflective layer 170 may have a single-layer structure to serve as an n-type ohmic contact electrode in itself and may also have a multilayer structure in which a thin n-type ohmic contact electrode is first formed on the nitrogen polarity (N-polarity) surface of the semiconductor layer 120, and then the reflective layer 170 is formed thereon using a material that is the same as or different from that of the n-type ohmic contact electrode and is electrically connected.

Meanwhile, in the present invention, the reflective layer 170 may be formed entirely on the nitrogen polarity (N-polarity) surface of the semiconductor layer 120 as shown in FIG. 3. In order to prevent re-deposition from occurring in advance when etching is performed to separate the reflective layer 170 into a unit of a chip on a chip-on-wafer, it is preferable that the reflective layer 170 be separated into chip units and formed using a photoresist (PR).

The chip-on-wafer manufactured according to the method S100 of manufacturing a chip-on-wafer for a micro-LED display according to the first embodiment of the present invention as described above has a structure in which the final support substrate 190, the separation layer S, the bonding layer 181, the ohmic contact electrode 130, the semiconductor layer 120, and the reflective layer 170 are sequentially stacked.

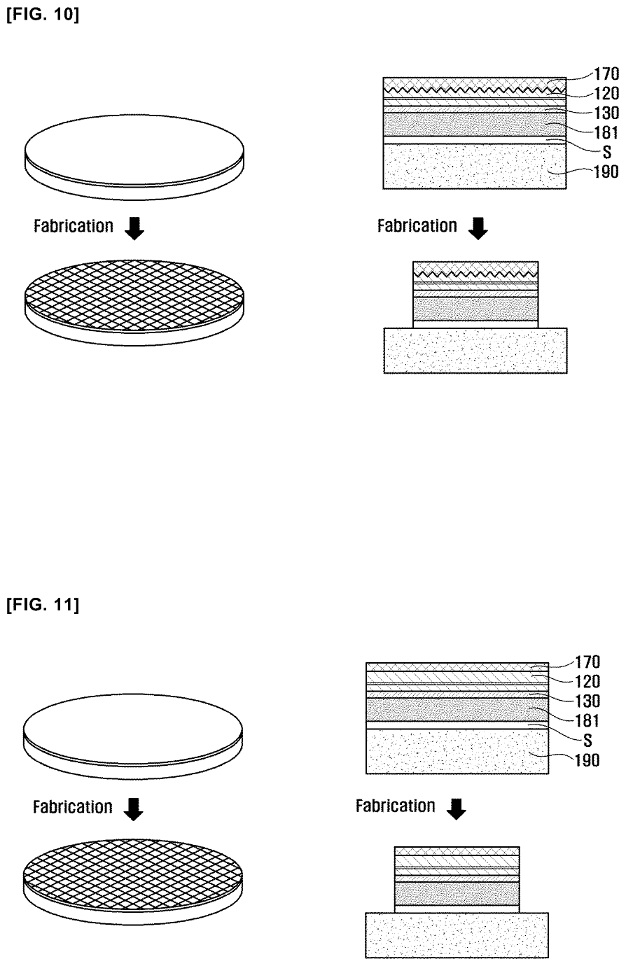

FIG. 10 illustrates a vertical chip manufactured using the chip-on-wafer manufactured according to the method of manufacturing a chip-on-wafer for a micro-LED display according to the first embodiment of the present invention.

As shown in FIG. 10, when a fabrication (Fab) process is performed on the chip-on-wafer manufactured according to the method S100 of manufacturing a chip-on-wafer for a micro-LED display according to the first embodiment of the present invention, the chip-on-wafer has a structure in which the final support substrate 190, the separation layer S, the bonding layer 181, the ohmic contact electrode 130, the semiconductor layer 120, and the reflective layer 170 are sequentially stacked, and a vertical chip, at a lower portion of which the p-type ohmic contact electrode 130 is provided and at an upper portion of which the reflective layer 170 serving as an n-type ohmic contact electrode is provided, may be manufactured on a wafer.

Afterwards, when a chip is transferred to a panel, an interposer, or the like to finally manufacture a display, the chip is optionally transferred through a one-time bonding or two-time bonding method according to a position at which a layer (or an electrode) serving as a reflector such as the reflective layer 170 is disposed. Since a chip manufactured through the present embodiment has a vertical chip structure with the p-type ohmic contact electrode 130 provided at a lower portion thereof, and the reflective layer 170 serving as an n-type ohmic contact electrode provided at an upper portion thereof, the final support substrate 190 is removed through a two-time bonding method using another temporary substrate, and then a panel is located on a surface from which the final support substrate 190 has been removed.

Hereinafter, a method S200 of manufacturing a chip-on-wafer for an LED display according to a second embodiment of the present invention will be described in detail with reference to the accompanying drawings.

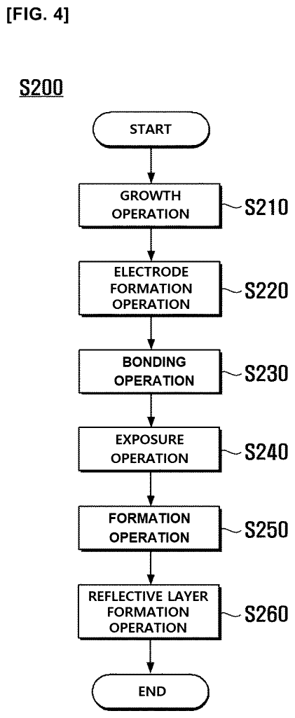

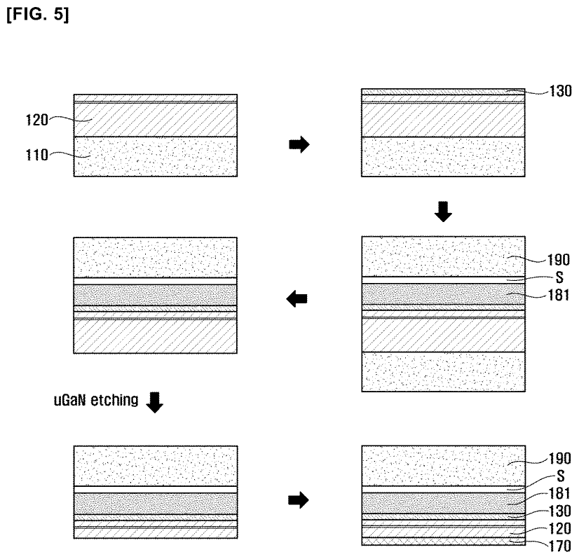

FIG. 4 is a flowchart of the method of manufacturing a chip-on-wafer for a micro-LED display according to the second embodiment of the present invention, and FIG. 5 illustrates a process of manufacturing a chip-on-wafer according to the method of manufacturing a chip-on-wafer for a micro-LED display according to the second embodiment of the present invention.

As shown in FIGS. 4 and 5, a chip-on-wafer is manufactured through a one-time bonding method, and the method S200 of manufacturing a chip-on-wafer for a micro-LED display according to the second embodiment of the present invention includes a growth operation S210, an electrode formation operation S220, a bonding operation S230, an exposure operation S240, a formation operation S250, and a reflective layer formation operation S260.

Here, since the growth operation S210 to the formation operation S250 are the same as those of the method S100 of manufacturing a chip-on-wafer for a micro-LED display according to the first embodiment of the present invention described above, redundant descriptions will be omitted.

The reflective layer formation operation S260 is an operation of forming a reflective layer 170 on one surface of a semiconductor layer 120 that is exposed and then etched by removing an initial growth substrate 110.

The reflective layer 170 may be made of Ag, Al, Au, Pd, Pt, Ni, Mo, Cu, Cr, Ti, TiW, ITO, IZO, ZnO, TiN, a DBR, an ODR, or a combination thereof, and in the present embodiment, the reflective layer 170 may be formed on one surface of the semiconductor layer 120, that is, a nitrogen polarity (N-polarity) surface.

Meanwhile, the reflective layer 170 may have a single-layer structure to serve as an n-type ohmic contact electrode in itself and may also have a multilayer structure in which a thin n-type ohmic contact electrode is first formed on the nitrogen polarity (N-polarity) surface of the semiconductor layer 120, and then the reflective layer 170 is formed thereon using a material that is the same as or different from that of the n-type ohmic contact electrode and is electrically connected.

Meanwhile, in the present invention, the reflective layer 170 may be formed entirely on the nitrogen polarity (N-polarity) surface of the semiconductor layer 120 as shown in FIG. 5. In order to prevent re-deposition from occurring in advance when etching is performed to separate the reflective layer 170 in a unit of a chip on a chip-on-wafer, it is preferable that the reflective layer 170 be separated into chip units and formed using a PR.

The chip-on-wafer manufactured according to the method S200 of manufacturing a chip-on-wafer for a micro-LED display according to the second embodiment of the present invention as described above has a structure in which a final support substrate 190, a separation layer S, a bonding layer 181, an ohmic contact electrode 130, the semiconductor layer 120, and the reflective layer 170 are sequentially stacked.

FIG. 11 illustrates a vertical chip manufactured using the chip-on-wafer manufactured according to the method of manufacturing a chip-on-wafer for a micro-LED display according to the second embodiment of the present invention.

As shown in FIG. 11, when a Fab process is performed on the chip-on-wafer manufactured according to the method S200 of manufacturing a chip-on-wafer for a micro-LED display according to the second embodiment of the present invention, the chip-on-wafer has a structure in which the final support substrate 190, the separation layer S, the bonding layer 181, the ohmic contact electrode 130, the semiconductor layer 120, and the reflective layer 170 are sequentially stacked, and a vertical chip, at a lower portion of which a p-type ohmic contact electrode 130 is provided and at an upper portion of which the reflective layer 170 serving as an n-type ohmic contact electrode is provided, may be manufactured on a wafer.

Afterwards, when a chip is transferred to a panel, an interposer, or the like to finally manufacture a display, the chip is optionally transferred through a one-time bonding or two-time bonding method according to a position at which a layer (or an electrode) serving as a reflector such as the reflective layer 170 is disposed. Since a chip manufactured through the present embodiment has a vertical chip structure with the p-type ohmic contact electrode 130 provided at a lower portion thereof, and the reflective layer 170 serving as an n-type ohmic contact electrode provided at an upper portion thereof, the final support substrate 190 is removed through a two-time bonding method using another temporary substrate, and then a panel is located on a surface from which the final support substrate 190 has been removed.

Hereinafter, a method S300 of manufacturing a chip-on-wafer for an LED display according to a third embodiment of the present invention will be described in detail with reference to the accompanying drawings.

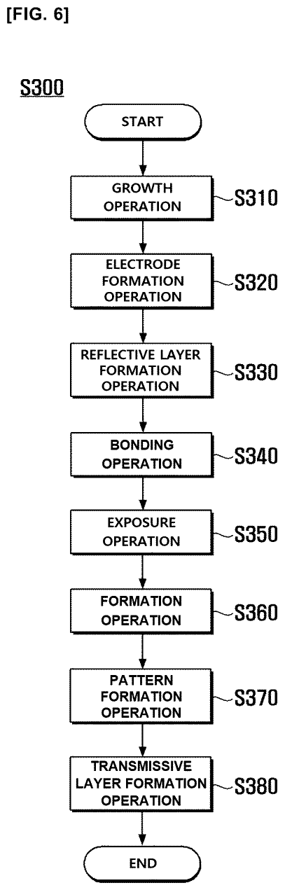

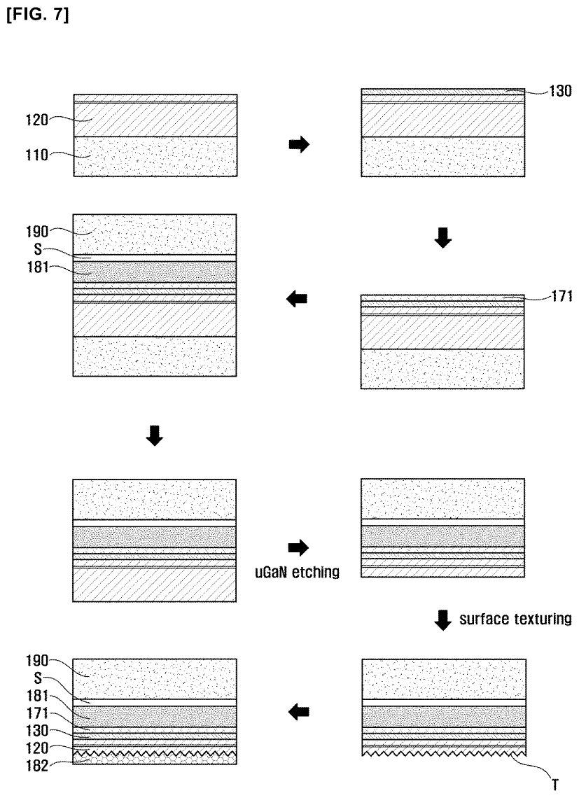

FIG. 6 is a flowchart of the method of manufacturing a chip-on-wafer for a micro-LED display according to the third embodiment of the present invention, and FIG. 7 illustrates a process of manufacturing a chip-on-wafer according to the method of manufacturing a chip-on-wafer for a micro-LED display according to the third embodiment of the present invention.

As illustrated in FIGS. 6 and 7, a chip-on-wafer is manufactured through a one-time bonding method, and the method S300 of manufacturing a chip-on-wafer for a micro-LED display according to the third embodiment of the present invention includes a growth operation S310, an electrode formation operation S320, a reflective layer formation operation S330, a bonding operation S340, an exposure operation S350, a formation operation S360, a pattern formation operation S370, and a transmissive layer formation operation S380.

Here, since the growth operation S310 and the electrode formation operation S320 are the same as those of the method S100 of manufacturing a chip-on-wafer for a micro-LED display according to the first embodiment of the present invention described above, redundant descriptions will be omitted.

The reflective layer formation operation S330 is an operation of forming a reflective layer 170 on an ohmic contact electrode 130.

The reflective layer 170 may be made of Ag, Al, Au, Pd, Pt, Ni, Mo, Cu, Cr, Ti, TiW, ITO, IZO, ZnO, TiN, a DBR, an ODR, or a combination thereof, and may have a single-layer structure or a multilayer structure, but does not form an ohmic contact.

Meanwhile, in the present invention, the reflective layer 170 may be formed entirely on the ohmic contact electrode 130 or may be separated into chip units and formed. As shown in FIG. 7, in order to prevent re-deposition from occurring in advance when etching is performed to separate the reflective layer 170 into a unit of a chip on a chip-on-wafer, it is preferable that the reflective layer 170 be separated into chip units using a PR.

The bonding operation S340 is an operation of bonding the reflective layer 170 to a final support substrate 190 through a bonding layer 181.

Here, the final support substrate 190 is a substrate that supports a structure of a chip that has undergone each operation of the method S300 of manufacturing a chip-on-wafer for a micro-LED display according to the third embodiment of the present invention. The support substrate 190 may be provided using a sapphire (α-phase Al₂O₃) substrate or glass with an adjusted CTE.

In addition, in the present embodiment, the bonding layer 181 may include a flowable oxide (FOₓ) such as SiO₂, SiNₓ, SiCN, AlN, Al₂O₃, SOG (liquid SiO₂), or HSQ to transmit generated light.

Meanwhile, in the bonding operation S340, a separation layer S may be formed on the support substrate 190, and then the reflective layer 170 may be bonded to the separation layer S. The separation layer S may be a layer that is sacrificed and separated when the final support substrate 190 is removed, and a material according to an LLO process may be used. Meanwhile, the separation layer S may be located on or below the bonding layer 181 according to the purpose, and when the bonding layer 181 performs a function of the separation layer S, the separation layer S may be omitted.

Since the exposure operation S350 to the pattern formation operation S370 are the same as those of the method S100 of manufacturing a chip-on-wafer for a micro-LED display according to the first embodiment of the present invention described above, redundant descriptions will be omitted.

The transmissive layer formation operation S380 is an operation of forming a transmissive layer 182 on one surface of a semiconductor layer 120 on which a surface texture pattern T is formed.

The transmissive layer 182 is made of a transparent and conductive material such that light from below is transmitted upward. In this case, a material of the transmissive layer 182 may include NiO, PtO, PdO, AgO₂, Au, Rh₂O₃, RuO₂, In₂O₃, SnO₂, ZnO, IZO, ITO, or IGZO.

Meanwhile, the transmissive layer 182 may have a single-layer structure to serve as an n-type ohmic contact electrode in itself and may also have a multilayer structure in which a thin n-type ohmic contact electrode is first formed on a nitrogen polarity (N-polarity) surface of the semiconductor layer 120, and then the transmissive layer 182 is formed thereon using a material that is the same as or different from that of the n-type ohmic contact electrode and is electrically connected.

The chip-on-wafer manufactured according to the method S300 of manufacturing a chip-on-wafer for a micro-LED display according to the third embodiment of the present invention as described above has a structure in which a final support substrate 190, a separation layer S, the bonding layer 181, the reflective layer 171, an ohmic contact electrode 130, the semiconductor layer 120, and the transmissive layer 182 are sequentially stacked.

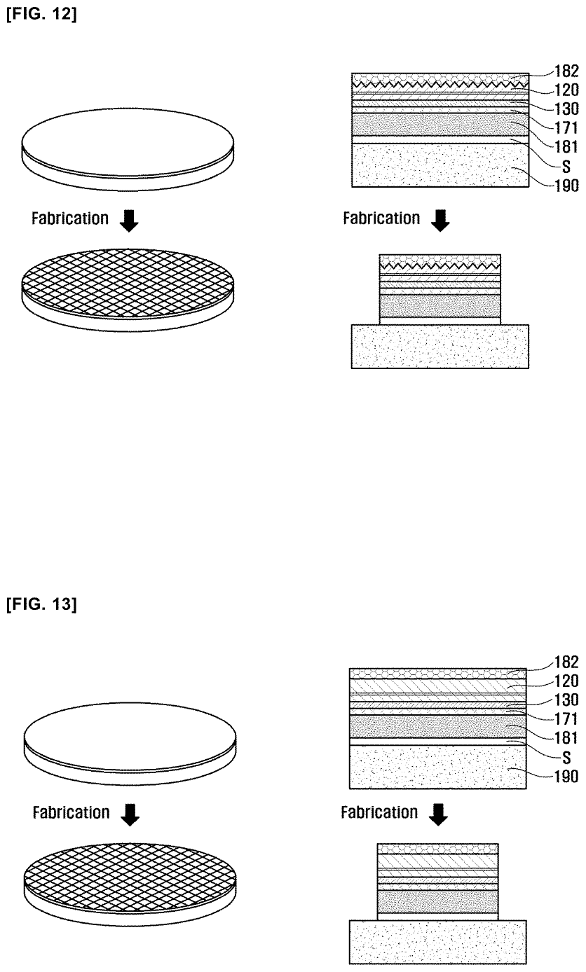

FIG. 12 illustrates a vertical chip manufactured using the chip-on-wafer manufactured according to the method of manufacturing a chip-on-wafer for a micro-LED display according to the third embodiment of the present invention.

As shown in FIG. 12, when a Fab process is performed on the chip-on-wafer manufactured according to the method S300 of manufacturing a chip-on-wafer for a micro-LED display according to the third embodiment of the present invention, the chip-on-wafer has a structure in which the final support substrate 190, the separation layer S, the bonding layer 181, the reflective layer 171, the ohmic contact electrode 130, the semiconductor layer 120, and the transmissive layer 182 are sequentially stacked, and a vertical chip, at a lower portion of which a p-type ohmic contact electrode 130 is provided together with the reflective layer 171 and at an upper portion of which the transmissive layer 182 serving as an n-type ohmic contact electrode is provided, may be manufactured on a wafer.

Afterwards, when a chip is transferred to a panel, an interposer, or the like to finally manufacture a display, the chip is optionally transferred through a one-time bonding or two-time bonding method according to a position at which a layer (or an electrode) serving as a reflector such as the reflective layer 171 is disposed. Since a chip manufactured through the present embodiment has a vertical chip structure with the p-type ohmic contact electrode 130 provided at a lower portion thereof together with the reflective layer 171, and the transmissive layer 182 serving as an n-type ohmic contact electrode provided at an upper portion thereof, the final support substrate 190 is removed through a two-time bonding method using another temporary substrate, and then a panel is located on a surface from which the final support substrate 190 has been removed.

Hereinafter, a method S400 of manufacturing a chip-on-wafer for an LED display according to a fourth embodiment of the present invention will be described in detail with reference to the accompanying drawings.

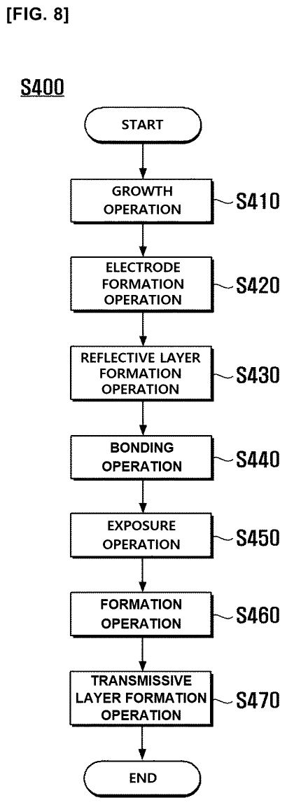

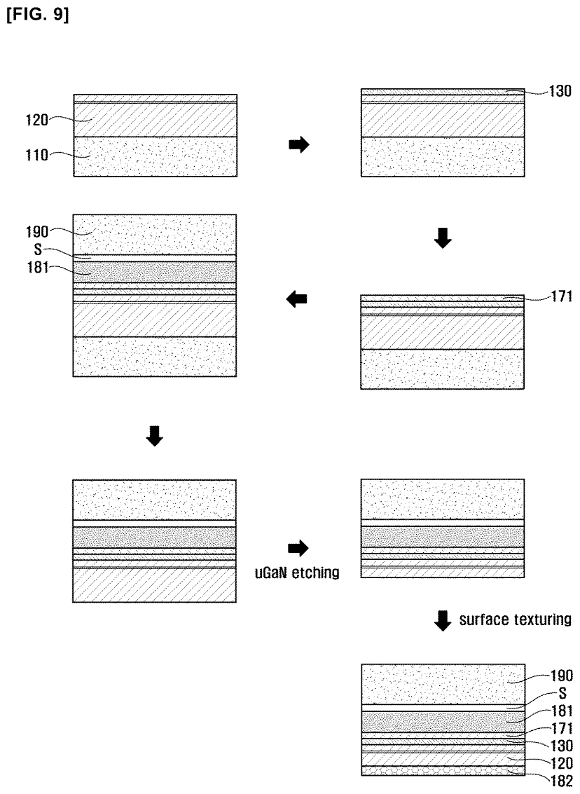

FIG. 8 is a flowchart of the method of manufacturing a chip-on-wafer for a micro-LED display according to the fourth embodiment of the present invention, and FIG. 9 illustrates a process of manufacturing a chip-on-wafer according to the method of manufacturing a chip-on-wafer for a micro-LED display according to the fourth embodiment of the present invention.

As shown in FIGS. 8 and 9, a chip-on-wafer is manufactured through a one-time bonding method, and the method S400 of manufacturing a chip-on-wafer for a micro-LED display according to the fourth embodiment of the present invention includes a growth operation S410, an electrode formation operation S420, a reflective layer formation operation S430, a bonding operation S440, an exposure operation S450, a formation operation S460, and a transmissive layer formation operation S470.

Here, since the growth operation S410 to the formation operation S460 are the same as those of the method S300 of manufacturing a chip-on-wafer for a micro-LED display according to the third embodiment of the present invention described above, redundant descriptions will be omitted.

The transmissive layer formation operation S470 is an operation of forming a transmissive layer 182 on one surface of a semiconductor layer 120 that is exposed and then etched by removing an initial growth substrate 110.

The transmissive layer 182 is made of a transparent and conductive material such that light from below is transmitted upward. In this case, a material of the transmissive layer 182 may include NiO, PtO, PdO, AgO₂, Au, Rh₂O₃, RuO₂, In₂O₃, SnO₂, ZnO, IZO, ITO, or IGZO.

Meanwhile, the transmissive layer 182 may have a single-layer structure to serve as an n-type ohmic contact electrode in itself and may also have a multilayer structure in which a thin n-type ohmic contact electrode is first formed on a nitrogen polarity (N-polarity) surface of the semiconductor layer 120, and then the transmissive layer 182 is formed thereon using a material that is the same as or different from that of the n-type ohmic contact electrode and is electrically connected.

The chip-on-wafer manufactured according to the method S400 of manufacturing a chip-on-wafer for a micro-LED display according to the fourth embodiment of the present invention as described above has a structure in which a final support substrate 190, a separation layer S, a bonding layer 181, a reflective layer 171, an ohmic contact electrode 130, the semiconductor layer 120, and the transmissive layer 182 are sequentially stacked.

FIG. 13 illustrates a vertical chip manufactured using the chip-on-wafer manufactured according to the method of manufacturing a chip-on-wafer for a micro-LED display according to the fourth embodiment of the present invention.

As shown in FIG. 13, when a Fab process is performed on the chip-on-wafer manufactured according to the method S400 of manufacturing a chip-on-wafer for a micro-LED display according to the fourth embodiment of the present invention, the chip-on-wafer has a structure in which the final support substrate 190, the separation layer S, the bonding layer 181, the reflective layer 171, the ohmic contact electrode 130, the semiconductor layer 120, and the transmissive layer 182 are sequentially stacked, and a vertical chip, at a lower portion of which a p-type ohmic contact electrode 130 is provided together with the reflective layer 171 and at an upper portion of which the transmissive layer 182 serving as an n-type ohmic contact electrode is provided, may be manufactured on a wafer.

Afterwards, when a chip is transferred to a panel, an interposer, or the like to finally manufacture a display, the chip is optionally transferred through a one-time bonding or two-time bonding method according to a position at which a layer (or an electrode) serving as a reflector such as the reflective layer 171 is disposed. Since a chip manufactured through the present embodiment has a vertical chip structure with the p-type ohmic contact electrode 130 provided at a lower portion thereof together with the reflective layer 171, and the transmissive layer 182 serving as an n-type ohmic contact electrode provided at an upper portion thereof, the final support substrate 190 is removed through a two-time bonding method using another temporary substrate, and then a panel is located on a surface from which the final support substrate 190 has been removed.

Although all of the components of the embodiments of the present invention may have been described as being assembled or operatively connected as one component, the present invention is not necessarily to the embodiments. That is, within the objective scope of the present invention, the respective components may be selectively and operatively combined as one or more components.

In addition, the terms “include,” “consist,” or “have” as described above mean that a corresponding component may be intrinsic, unless specifically stated otherwise, and it should interpreted as including other components rather than excluding other components. All terms including technical or scientific terms have the same meanings as those commonly understood by those skilled in the art to which the present invention pertains, unless defined otherwise. Commonly used terms such as those defined in a commonly used dictionary should be construed as being consistent with the context of the relevant art and are not to be construed in an idealized or overly formal sense unless expressly so defined in the present invention.

The above description is merely illustrative of the technical idea of the present invention, and those skilled in the art to which the present invention pertains may make various modifications and variations without departing from the essential characteristics of the present invention.

Accordingly, the embodiments disclosed in the present invention are not intended to limit the technical idea of the present invention, but are for illustrative purposes, and the scope of the technical idea of the present invention is not limited by these embodiments. The spirit and scope of the present disclosure should be interpreted from the appended claims and encompass all equivalents falling within the scope of the appended claims.

1. A method of manufacturing a chip-on-wafer for a micro-light-emitting diode (LED) display, the method comprising:
a growth operation of epitaxially growing a semiconductor layer on a growth substrate;
an electrode formation operation of forming an ohmic contact electrode on the semiconductor layer;
a bonding operation of bonding the ohmic contact electrode to a support substrate; and
an exposure operation of removing the growth substrate to expose one surface of the semiconductor layer.

2. The method of claim 1, further comprising a formation operation of etching the exposed one surface of the semiconductor layer to form the semiconductor layer to have a preset thickness.

3. The method of claim 2, wherein the growth operation includes sequentially and epitaxially growing a third semiconductor region, a second semiconductor region, an active region, and a first semiconductor region,
the formation operation includes etching the exposed third semiconductor region to form the semiconductor layer to have the preset thickness, and
the third semiconductor region is an undoped semiconductor region.

4. The method of claim 1, further comprising a pattern formation operation of forming a surface texture pattern on the exposed one surface of the semiconductor layer.

5. The method of claim 4, further comprising a reflective layer formation operation of forming a reflective layer on the one surface of the semiconductor layer on which the surface texture pattern is formed.

6. The method of claim 1, further comprising a reflective layer formation operation of forming a reflective layer on the exposed one surface of the semiconductor layer.

7. The method of claim 5, wherein the reflective layer is in ohmic contact with the one surface of the semiconductor layer.

8. The method of claim 6, wherein the reflective layer is in ohmic contact with the one surface of the semiconductor layer.

9. The method of claim 1, wherein the bonding operation includes forming a separation layer on the support substrate and then bonding the one surface of the semiconductor layer to the separation layer.

10. A method of manufacturing a chip-on-wafer for a micro-light-emitting diode (LED) display, the method comprising:
a growth operation of epitaxially growing a semiconductor layer on a growth substrate;
an electrode formation operation of forming an ohmic contact electrode on the semiconductor layer;
a reflective layer formation operation of forming a reflective layer on the ohmic contact electrode;
a bonding operation of bonding the reflective layer to a support substrate; and
an exposure operation of removing the growth substrate to expose one surface of the semiconductor layer.

11. The method of claim 10, further comprising a formation operation of etching the exposed one surface of the semiconductor layer to form the semiconductor layer to have a preset thickness.

12. The method of claim 11, wherein the growth operation includes sequentially and epitaxially growing a third semiconductor region, a second semiconductor region, an active region, and a first semiconductor region,
the formation operation includes etching the exposed third semiconductor region to form the semiconductor layer to have the preset thickness, and
the third semiconductor region is an undoped semiconductor region.

13. The method of claim 10, further comprising a pattern formation operation of forming a surface texture pattern on the exposed one surface of the semiconductor layer.

14. The method of claim 13, further comprising a transmissive layer formation operation of forming a transmissive layer on the one surface of the semiconductor layer on which the surface texture pattern is formed.

15. The method of claim 10, further comprising a transmissive layer formation operation of forming a transmissive layer on the exposed one surface of the semiconductor layer.

16. The method of claim 14, wherein the transmissive layer is in ohmic contact with the one surface of the semiconductor layer.

17. The method of claim 15, wherein the transmissive layer is in ohmic contact with the one surface of the semiconductor layer.

18. The method of claim 10, wherein the bonding operation includes forming a separation layer on the support substrate and then bonding the one surface of the semiconductor layer to the separation layer.
